(19) United States
(12) Patent Application Publication
(10) Pub. No.: US 2023/0403921 A1
(43) Pub. Date: Dec. 14, 2023

(54) METHOD FOR MANUFACTURING DISPLAY PANEL WITH NO COLOR UNEVENNESS USING INKJET

(71) Applicant: PUKYONG NATIONAL UNIVERSITY INDUSTRY-UNIVERSITY COOPERATION FOUNDATION, Busan (KR)

(72) Inventor: Dong Youn SHIN, Busan (KR)

(21) Appl. No.: 18/231,130

(22) Filed: Aug. 7, 2023

Related U.S. Application Data
(63) Continuation of application No. PCT/KR2021/004494, filed on Apr. 9, 2021.

(30) Foreign Application Priority Data
Apr. 7, 2021 (KR) 10-2021-0045244

(51) Int. Cl. H10K 71/13; H01L 33/00

(52) U.S. Cl. CPC H10K 71/135; H01L 33/005

(57) ABSTRACT

Proposed is a method for manufacturing display panel with no color unevenness using an inkjet and, more particularly, to a method for manufacturing display panel with no color unevenness using an inkjet. The method may include applying the same amount of ink droplets to respective subpixels having randomly different areas so that the thickness of a coating film is randomly varied. A color deviation of the subpixels can be randomized so that the human eye may not perceive color unevenness.

### CROSS-REFERENCE TO RELATED APPLICATIONS

This application is a continuation application, and claims the benefit under 35 U.S.C. § 120 and § 365 of PCT Application No. PCT/KR2021/004494, filed on Apr. 9, 2021, which claims priority to Korean Patent Application No. 10-2021-0045244 filed on Apr. 7, 2021, each of which are hereby incorporated by reference in their entirety.

### BACKGROUND

### Technical Field

The present disclosure relates to a method for manufacturing display panel with no color unevenness using an inkjet and, more particularly, to a method for manufacturing display panel with no color unevenness using an inkjet wherein, by applying the same amount of ink droplets to respective subpixels having randomly different areas so that the thickness of a coating film is randomly varied, a color deviation of the subpixels is randomized so that the human eye does not perceive color unevenness.

### Description of Related Technology

In general, a display panel consists of a matrix of pixels, each made up of a red, a green, and a blue subpixel. Conventionally, a general method of configuring subpixels of a display panel involves applying a color resist of one color among the three colors of red, green, and blue to a display panel, and by using a photolithography process, leaving the color resist of the desired color only in the desired subpixel and repeating the whole process to produce a color filter of the display panel.

Yet, manufacturing in this way results in a significant waste of material, and for materials, such as organic light-emitting diodes (OLED) and quantum dots (QD), that are expensive and vulnerable to post-processes using chemicals and high temperatures, it is difficult to use the photolithography process.

### SUMMARY

One aspect is a method for manufacturing display panel with no color unevenness using an inkjet, with the panel having excellent productivity and visually imperceptible color deviation between subpixels by minimizing the number of inkjet patterns per display panel without complicating a drive circuit of an inkjet print head.

Another aspect is a method for manufacturing display panel with no color unevenness using an inkjet. The method includes: forming a black matrix to form a plurality of black matrices on a substrate so that areas of subpixels are randomly different; ejecting RGB ink to lay down the same amount of an RGB ink to the subpixels from a plurality of inkjet print head nozzles; and drying the RGB ink sprayed on the subpixels with a dryer or curing with an ultraviolet curing device.

In the method for manufacturing display panel with no color unevenness using an inkjet according to the embodiment, in the forming a black matrix, the subpixels may be formed using any one of photoresist, screen printing, sandblasting and lift-off processes, and the plurality of black matrices may be formed on the substrate so that the areas of the subpixels are randomly different.

In the method for manufacturing display panel with no color unevenness using an inkjet according to the embodiment, the black matrix may be composed of subpixels with different random areas.

In the method for manufacturing display panel with no color unevenness using an inkjet according to the embodiment, the black matrix may be primarily composed of reference subpixels, and one or more types of subpixels having different sizes from the reference subpixels may be randomly arranged.

In the method for manufacturing display panel with no color unevenness using an inkjet according to the embodiment, the RGB ink may be an RGB ink for a color filter.

In the method for manufacturing display panel with no color unevenness using an inkjet according to the embodiment, the RGB ink may be an RGB ink for an organic light-emitting diode (OLED) display panel.

In the method for manufacturing display panel with no color unevenness using an inkjet according to the embodiment, the RGB ink may be an RGB ink for a quantum dot (QD)-based display panel.

In the method for manufacturing display panel with no color unevenness using an inkjet according to the embodiment, the RGB ink may be a nanorod ink for a light emitting diode (LED) display panel.

According to a method for manufacturing display panel with no color unevenness using an inkjet according to an embodiment of the present disclosure, since a plurality of black matrices are formed on a substrate such that subpixels have randomly different areas, the same amount of RGB ink from a plurality of nozzles of an inkjet print head is ejected to the subpixels, and the RGB ink ejected on the subpixels is dried with a dryer, a drive circuit of an inkjet print head is not complicated and the number of ink droplet application per subpixel can be minimized, resulting in excellent productivity.

That is, since ejecting conditions of the plurality of nozzles of the inkjet print head are not different for each subpixel, the drive circuit of the inkjet print head is not complicated and rapid ink ejection is possible, resulting in excellent productivity.

### BRIEF DESCRIPTION OF THE DRAWINGS

FIG. 1 is a flowchart illustrating a method for manufacturing display panel with no color unevenness using an inkjet according to an embodiment of the present disclosure.

FIG. 2 is a process diagram of a method for manufacturing display panel with no color unevenness using an inkjet the according to the embodiment of the present disclosure. (a) of FIG. 2 illustrates a black matrix (BM) forming process, (b) of FIG. 2 illustrates an RGB ink jetting process, and (c) of FIG. 2 illustrates a drying process.

FIG. 3 illustrates the formation of a black matrix on a substrate through a photoresist process as shown in FIG. 2 ((a) of FIG. 3), and a view illustrating that RGB ink is ejected on subpixels formed by the black matrix as shown in FIG. 2 ((b) of FIG. 3).

FIG. 4 illustrates the black matrix composed of random subpixels according to the embodiment of the present disclosure. (a) of FIG. 4 illustrates a case where the size of each subpixel is randomly different, and (b) of FIG. 4 illustrates a case where a finite number of subpixels having different sizes are randomly arranged.

FIG. 5 illustrates examples of corner formation of a subpixel according to the embodiment of the present disclosure.

FIG. 6 illustrates methods for calibrating the volume of ink droplets of an inkjet print head according to the related art.

FIG. 7 illustrates methods for removing color stains of a display panel according to the related art. (a) of FIG. 7 illustrates an intra-pixel mixing method, and (b) of FIG. 7 illustrates an inter-pixel mixing method.

### DETAILED DESCRIPTION

Pattern technology such as inkjet printing in which a desired amount of ink can be applied to a desired area has attracted the attention of the display industry. However, there is a problem in that when manufacturing display panels using inkjet technology, the volume of an ink droplet ejected from each nozzle is not exactly the same, and as a result, the amount of ink applied to each subpixel is different, causing uneven color on a display panel.

Korean Patent Application Publication No. 10-2010-0081392 (hereinafter referred to as “related art”) discloses a device for controlling an ejected amount of droplets out of an inkjet print head. The device includes: an inkjet print head equipped with a plurality of nozzles; a camera capturing images of ink droplets ejected from the plurality of nozzles of the inkjet print head on a display panel; an image analysis unit that analyzes the images captured by the camera, extracts an amount of ink droplets ejected on the display panel, and outputs a signal for the amount of ink droplets; and a controller that receives the signal for the amount of ink droplets from the image analysis unit and outputs a control signal to the inkjet print head to make the ejected amounts of droplets out of the plurality of nozzles uniform.

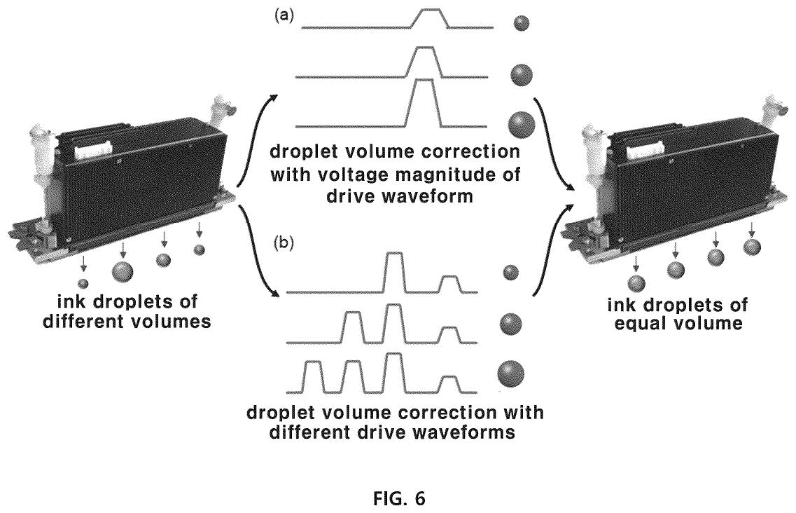

In the related art, after photographing the amount of ink droplets ejected for all subpixels of the same area to calculate volume, the magnitude of a voltage applied to the nozzles is controlled accordingly so that the volume of the ink droplets ejected from the nozzles of the inkjet print head is the same [(a) of FIG. 6], or different drive voltage waveforms are applied to individual nozzles at a required time [(b) of FIG. 6]. However, this method has a problem that a drive circuit of the controller for driving individual nozzles of the inkjet print head becomes complicated.

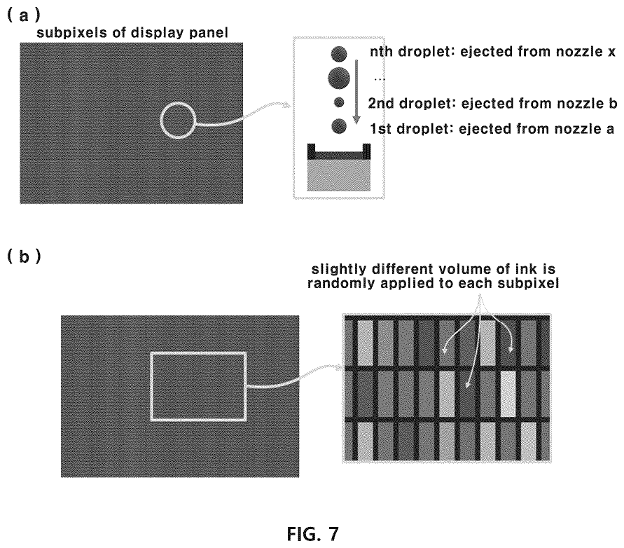

Nevertheless, since the volume of ink droplets discharged from the plurality of nozzles of the inkjet print head cannot be adjusted perfectly equally, color unevenness occurs on display panels produced by inkjet. In order to solve this problem, by filling each subpixel with ink droplets ejected from different nozzles [(a) of FIG. 7], the ink volume deviation between subpixels may be statistically reduced. However, if patterning is performed n times per display panel to place ink droplets discharged from the plurality of, that is, n number of nozzles for each subpixel, productivity decreases to 1/n.

An alternative approach is to manufacture a display panel to have a degree of unevenness that is visually undetectable by giving up having the same amount of ink for each subpixel and randomly having slightly different color deviations [(b) of FIG. 7]. However, for this method, different drive waveforms need to be applied to individual nozzles of the inkjet print head in order to discharge different amounts of ink droplets to each subpixel, which makes the drive circuit of the controller that drives the individual nozzles of the inkjet print head complicated.

In describing the embodiments of the present disclosure, if it is decided that the detailed description of known technologies related to the present disclosure makes the subject matter of the embodiments described herein unclear, the detailed description will be omitted. In addition, terms to be described later are terms defined in consideration of functions in the present disclosure, which may vary according to the intention or custom of a user or operator. Therefore, the definition thereof should be made on the basis of the contents throughout this specification. Terms used in the detailed description are only for describing the embodiments of the present disclosure, and should not be construed as limiting in any way. Singular forms are intended to include plural forms unless the context clearly indicates otherwise. It will be further understood that the terms “comprise” or “have” used in this specification, specify the presence of stated features, steps, operations, components, parts, or a combination thereof, but do not preclude the presence or addition of one or more other features, numerals, steps, operations, components, parts, or a combination thereof.

In each system shown in the figures, elements in some cases each have the same or different reference numbers, suggesting that the elements represented may be different or similar. However, the elements may have different implementations and may work with some or all of the systems shown or described herein. Various elements shown in the drawings may be the same or different. Which one is called the first element and which one is called the second element is arbitrary.

In this specification, when any one component “transmits”, “transfers”, or “provides” data or signals to another component, this includes transmission of data or signals from one component directly to another component, as well as transmission of data or signals to another component via at least one other component.

Hereinafter, embodiments of the present disclosure will be described in detail with reference to the drawings.

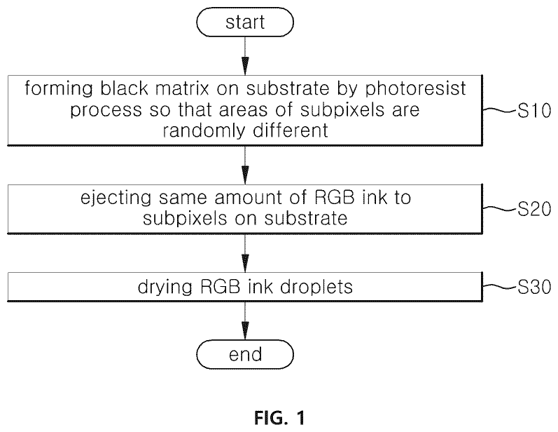

FIG. 1 is a flowchart illustrating a method for manufacturing display panel with no color unevenness using an inkjet according to an embodiment of the present disclosure.

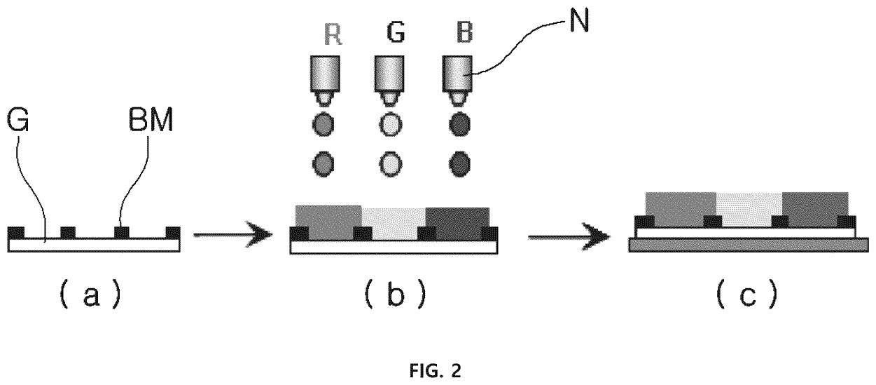

FIG. 2 is a process diagram of a method for manufacturing display panel with no color unevenness using an inkjet the according to the embodiment of the present disclosure. (a) of FIG. 2 illustrates a black matrix BM forming process, (b) of FIG. 2 illustrates an RGB ink jetting process, and (c) of FIG. 2 illustrates a drying process.

A method for manufacturing display panel with no color unevenness using an inkjet according to the embodiment of the present disclosure includes: forming a black matrix (S10); spraying RGB ink (S20); and drying (S30).

In the step of forming (S10) a black matrix BM, to configure a pixel, a plurality of black matrices BM are formed on a substrate G (e.g., glass substrate) so that areas of subpixels (S) expressing R (red), G (green), and B (blue) values are randomly different.

To form black matrices BM on the substrate G, a photoresist process is used, for example. The photoresist process includes a photoresist application process, an exposure process using a mask, and a development process. Instead of using a photoresist process, processes such as screen printing, sandblasting, and lift-off may be used by applying a barrier rib forming method of plasma display panel (PDP).

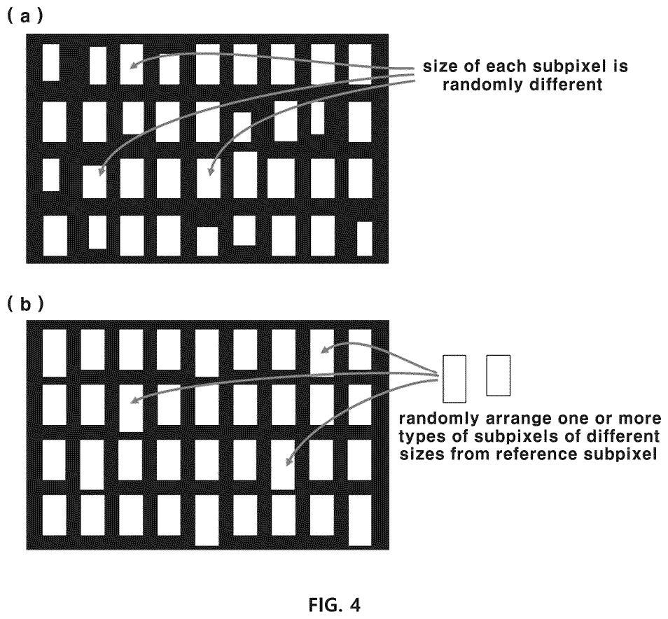

As shown in (a) of FIG. 4, subpixels constituting the black matrix may have randomly different sizes. Alternatively, as shown in (b) of FIG. 4, black matrices may be formed by randomly arranging one or more types of subpixels of different sizes in a basic black matrix composed of subpixels of the same size A.

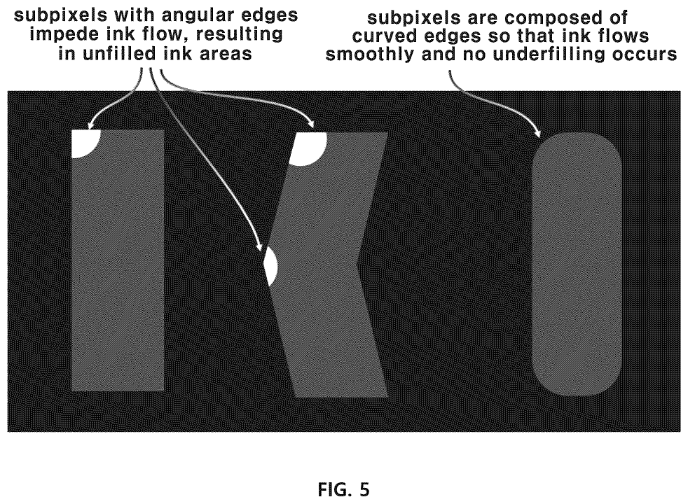

At this time, it is preferable that the subpixels constituting the black matrix are formed without angled corners so as not to interfere with the flow of ink as shown in FIG. 5. When subpixels have sharp-angled corners, ink flow in the subpixels may be obstructed, resulting in defective areas not filled with ink.

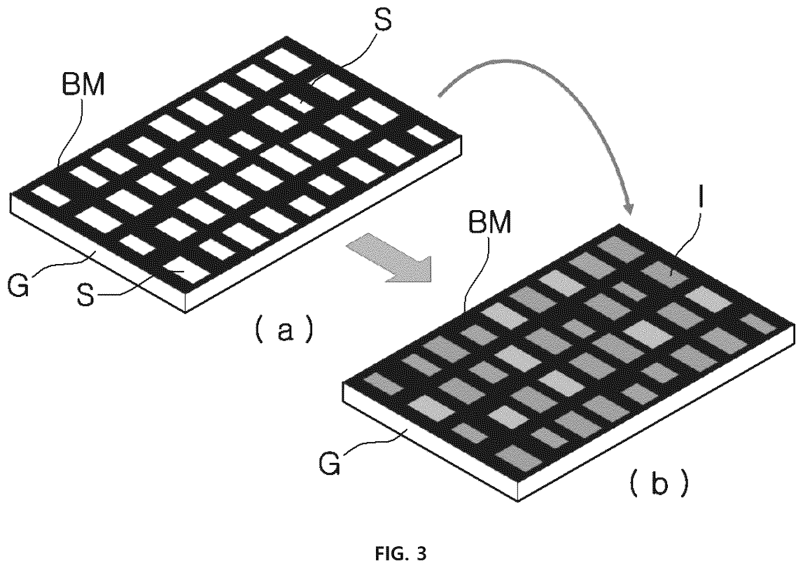

(a) of FIG. 3 illustrates the formation of a black matrix BM on a substrate G through a photoresist process. At this time, a plurality of subpixels S having randomly different areas are formed on the substrate G by a plurality of black matrices BM.

In the step of ejecting (S20) RGB ink, the same amount of RGB ink is ejected from a plurality of inkjet print head nozzles N to the subpixels S having randomly different areas. The ejected RGB ink is different depending on the type of display panel to be manufactured. That is, to manufacture color filters for liquid crystal display (LCD), RGB ink for color filters is used, to manufacture organic light emitting diodes (OLED) display panels, RGB ink for OLED is used, to manufacture quantum dot (QD)-based display panels, RGB ink with QD is used, and to manufacture light emitting diode (LED) display panels, ink for nanorods is used.

(b) of FIG. 3 illustrates that RGB ink I is ejected from a plurality of inkjet print head nozzles N to subpixels S having randomly different areas formed on a substrate G by black matrices BM.

When the same amount of RGB ink droplets is applied to each of the subpixels S, since the subpixels S have different areas, accordingly, the thickness of a coating film formed on the subpixels S is minutely and randomly different from each other. Thus, when the display panel is operated, the color deviation of the subpixels S is random, so that the human eye does not perceive color unevenness.

In the step of drying (S30), the RGB ink I ejected to the subpixels S in the above step of ejecting (S20) RGB ink is dried by a dryer. Alternatively, assuming that UV-curable ink is used, the RGB ink I filled in the subpixels S is cured with an ultraviolet curing machine equipped with an ultraviolet lamp.

According to the method for manufacturing display panel with no color unevenness using an inkjet according to the embodiment of the present disclosure, since the plurality of black matrices are formed on the substrate G such that the subpixels S have randomly different areas, the same amount of RGB ink from the plurality of inkjet print head nozzles N is ejected to the subpixels S, and the RGB ink ejected on the subpixels S is dried with the dryer or is cured with an ultraviolet curing machine, a drive circuit of an inkjet print head is not complicated and it is not necessary to repeat the application of ink droplets to the subpixel S numerous times, resulting in excellent productivity.

That is, since ejecting conditions of the plurality of nozzles of the inkjet print head are not different for each subpixel, the drive circuit of the inkjet print head is not complicated and there is no need to eject ink droplets from multiple nozzles per subpixel for intra-pixel mixing, resulting in excellent productivity.

Although optimal embodiments have been disclosed and specific terms are used in the drawings and specifications, these are only used for the purpose of explaining the embodiments of the present disclosure, and are not used to limit the meaning or scope of the present disclosure described in the claims. Accordingly, those skilled in the art will understand that various modifications and equivalent other embodiments are possible therefrom. Therefore, the true technical scope of protection of the present disclosure should be determined by the technical spirit of the appended claims.

What is claimed is:

1. A method for manufacturing a display panel with no color unevenness using an inkjet, the method comprising:
forming a black matrix to form a plurality of black matrices on a substrate so that areas of subpixels are randomly different;
ejecting an RGB ink to eject the same amount of the RGB ink to the subpixels from a plurality of inkjet print head nozzles; and
drying the RGB ink sprayed on the subpixels with a dryer or curing with an ultraviolet curing device.

2. The method of claim 1, wherein in forming the black matrix, the subpixels are formed using any one of photoresist, screen printing, sandblasting, or lift-off processes, and wherein the plurality of black matrices are formed on the substrate so that the areas of the subpixels are randomly different.

3. The method of claim 1, wherein the black matrix comprises subpixels with different random areas.

4. The method of claim 1, wherein the black matrix comprises reference subpixels, and wherein one or more types of subpixels having different sizes from the reference subpixels are randomly arranged.

5. The method of claim 1, wherein the RGB ink comprises an RGB ink for a color filter.

6. The method of claim 1, wherein the RGB ink comprises an RGB ink for an organic light-emitting diode (OLED) display panel.

7. The method of claim 1, wherein the RGB ink comprises an RGB ink for a quantum dot (QD)-based display panel.

8. The method of claim 1, wherein the RGB ink comprises a nanorod ink for a light emitting diode (LED) display panel.
